(19) United States
(12) Patent Application Publication
(10) Pub. No.: US 2015/0263099 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventors: Yasuhiro Isobe, Kanazawa Ishikawa (JP); Naoharu Sugiyama, Komatsu Ishikawa (JP)

(21) Appl. No.: 14/482,143

(22) Filed: Sep. 10, 2014

(30) Foreign Application Priority Data
Mar. 13, 2014 (JP) 2014-050877

(51) Int. Cl. H01L 29/201; H01L 29/36; H01L 29/778; H01L 29/20

(52) U.S. Cl. CPC H01L 29/201; H01L 29/2003; H01L 29/36; H01L 29/7787

(57) ABSTRACT

In accordance with an embodiment, a semiconductor device includes a GaN layer and a first AlₓGa₁₋ₓN layer (0≦X<1). The first AlₓGa₁₋ₓN layer (0≦X<1) is located on the GaN layer. The first AlₓGa₁₋ₓN layer (O≦X<1) is located in contact with the GaN layer. The first AlₓGa₁₋ₓN layer (0≦X<1) includes carbon (C).

### CROSS REFERENCE TO RELATED APPLICATIONS

This application is based upon and claims the benefit of priority from the prior Japanese Patent Application No. 2014-050877, filed on Mar. 13, 2014, the entire contents of which are incorporated herein by reference.

### FIELD

Embodiments described herein relate generally to a semiconductor device.

### BACKGROUND

When GaN is grown on a silicon (Si) substrate, tensile stress is generated in the GaN layer due to a lattice constant difference (about 17%) and a thermal expansion coefficient difference (about 56%) between silicon (Si) and GaN. Such a tensile stress causes a problem that it is difficult to obtain a high-quality crack-free GaN-based nitride semiconductor epitaxial film.

### BRIEF DESCRIPTION OF THE DRAWINGS

In the accompanying drawings:

FIG. 1 is an example of a schematic sectional view showing a semiconductor device according to Embodiment 1;

FIG. 2 is an example of a diagram schematically showing the accumulation of compressive stress according to a reference example;

FIG. 3 is an example of a diagram schematically showing the accumulation of compressive stress in the semiconductor device shown in FIG. 1;

FIG. 4 is an example of a schematic sectional view showing one modification of the semiconductor device shown in FIG. 1; and

FIG. 5 is an example of a schematic sectional view showing the general structure of a semiconductor device according to Embodiment 2.

### DETAILED DESCRIPTION

In accordance with an embodiment, a semiconductor device includes a GaN layer and a first AlₓGa₁₋ₓN layer (0≦X<1). The first AlₓGa₁₋ₓN layer (0≦X<1) is located in contact with the GaN layer and includes carbon (C).

Embodiments will now be explained with reference to the accompanying drawings. Like components are provided with like reference signs throughout the drawings and repeated descriptions thereof are appropriately omitted.

It is to be noted that the accompanying drawings illustrate the invention and assist in the understanding of the illustration and that the shapes, dimensions, and ratios in each of the drawings are different in some parts from those in an actual apparatus.

In the specification of the present application, “stacking” not only includes stacking layers in contact with each other but also includes staking layers with another layer interposed in between. “Providing on” not only includes providing a layer in direct contact with a layer but also includes providing a layer on a layer with another layer interposed therebetween.

### (1) Embodiment 1

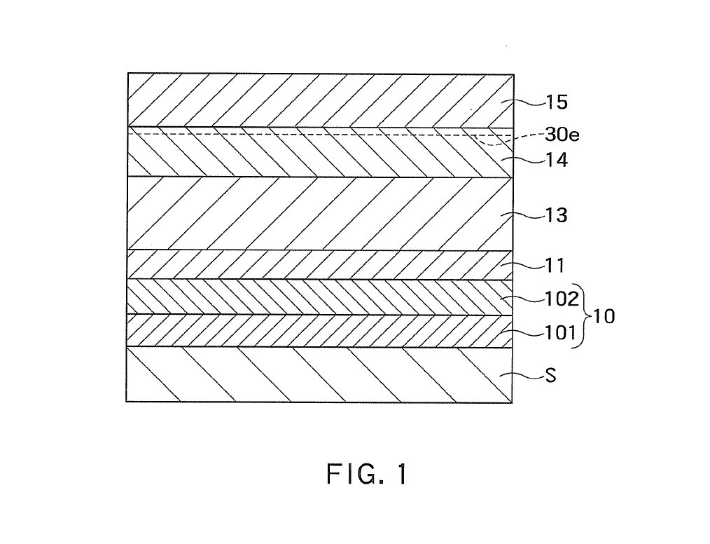

FIG. 1 is an example of a schematic sectional view showing a semiconductor device according to Embodiment 1. The semiconductor device according to the present embodiment includes a substrate S, a buffer layer 10, a u-GaN layer 11, a C-AlₓGa₁₋ₓN layer 13, an i-GaN layer 14, and an AlₓGa₁₋ₓN layer 15.

In the present embodiment, the substrate S is a silicon

(Si) substrate comprising a (111) plane. The thickness of the silicon (Si) substrate is, for example, 500 μm or more and 2 mm or less, and is preferably 700 μm or more and 1.5 mm or less. The substrate S may be a base material having a thin layer silicon (Si) stacked on the surface thereof. When the base material having the thin layer silicon (Si) stacked thereon is used, the thickness of the thin layer silicon (Si) is, for example, 5 nm or more and 500 nm or less.

The buffer layer 10 includes an AlN layer 101 provided on the substrate S in contact with the substrate S, and an Al_{y}Ga_{1-y}N layer (0<y<1) 102 provided on the AlN layer 101 in contact with the AlN layer 101. The thickness of the AlN layer 101 is, for example, 50 nm or more and 500 nm or less, and is preferably 100 nm or more and 300 nm or less. The Al_{y}Ga_{1-y}N layer (0<y<1) 102 may have, for example, a thickness of 100 nm or more and 1000 nm or less, and may be formed by stacking a plurality of layers having an aluminum (Al) composition. When a plurality of layers having the aluminum (Al) composition are stacked, the Al_{y}Ga_{1-y}N layer (0<y<1) 102 may have, for example, a stack structure in which an Al_{y}Ga_{1-y}N layer (0.3<y<0.7) and an Al_{z}Ga_{1-z}N layer (0.05<z<0.3) are stacked in this order. However, no Al_{y}Ga_{1-y}N layer (0<y<1) 102 may be needed depending on the thickness of the whole semiconductor device or the design of the semiconductor device.

The C-AlₓGa₁₋ₓN layer 13 is an AlₓGa₁₋ₓN layer (0≦X<1) which is provided on the buffer layer 10 and which includes carbon (C). The C-AlₓGa₁₋ₓN layer 13 has, for example, a thickness of 500 nm or more and 10 μm or less, and the concentration of carbon (C) is, for example, 5×10¹⁷ cm⁻³ or more and 5×10¹⁹ cm⁻³ or less. In a preferred embodiment, in, for example, an AlₓGa₁₋ₓN layer (X=0), the concentration of carbon (C) to be added is 1×10¹⁸ cm⁻³ or more and 1×10¹⁹ cm⁻³ or less, and the thickness is 0.5 μm or more and 5 μm or less. In, for example, an AlₓGa₁₋ₓN layer (X=0.03), the concentration of carbon (C) to be added is 8×10¹⁷ cm⁻³ or more and 5×10¹⁸ cm⁻³ or less, and the thickness is 0.5 μm or more and 3 μm or less. In the present embodiment, the C-AlₓGa₁₋ₓN layer 13 corresponds to, for example, a first AlₓGa₁₋ₓN layer.

The undoped-GaN (hereinafter briefly referred to as a “u-GaN”) layer 11 which is intentionally formed without the addition of an impurity is provided to be interposed between the buffer layer 10 and the C-AlₓGa₁₋ₓN layer 13. The u-GaN layer 11 is a GaN layer which is intentionally formed without the addition of an impurity, and has a thickness of, for example, 100 nm or more and 2 μm or less, and preferably has a thickness of 200 nm or more and 1 μm or less. The impurity concentration of the u-GaN layer 11 is less than 5×10¹² cm⁻³ regarding any of carbon (C), oxygen (O), and silicon (Si). Although the dislocation density included in the buffer layer 10 is 1×10¹⁰ cm⁻² or more, it is possible to obtain nitride semiconductor crystal in which the threading dislocation density of a nitride-based semiconductor layer to be stacked in the upper layer is less than 2×10⁹ cm⁻² by interposing the u-GaN layer 11. If the u-GaN layer 11 is not interposed in the present semiconductor device, the threading dislocation density of the nitride-based semiconductor layer to be stacked in the upper layer would be 2×10⁹ cm⁻² or more.

The i-GaN layer 14 is provided on the C-AlₓGa₁₋ₓN layer 13. The impurity concentration of the i-GaN layer 14 is preferably lower than the impurity concentration of the u-GaN layer 11. The thickness of the i-GaN layer 14 is, for example, 0.5 μm or more and 3 μm or less, and the impurity concentration of the i-GaN layer 14 is less than 3×10¹⁷ cm⁻³ regarding any of carbon (C), oxygen (O), and silicon (Si).

The AlₓGa₁₋ₓN layer 15 is formed on the i-GaN layer 14, and includes non-doped or n-type AlₓGa₁₋ₓN (0<X≦1). A two-dimensional electron gas 30e is generated in the vicinity of a boundary in the i-GaN layer 14 between the i-GaN layer 14 and the AlₓGa₁₋ₓN layer 15. Thus, the i-GaN layer 14 functions as a channel. In the present embodiment, the AlₓGa₁₋ₓN layer 15 corresponds to, for example, a second AlₓGa₁₋ₓN layer.

In the present embodiment, a semiconductor device which uses a GaN-on-Si epitaxial substrate and which has a breakdown voltage of 1000 V or more is obtained by stacking the thick nitride-based semiconductor layer on the substrate S.

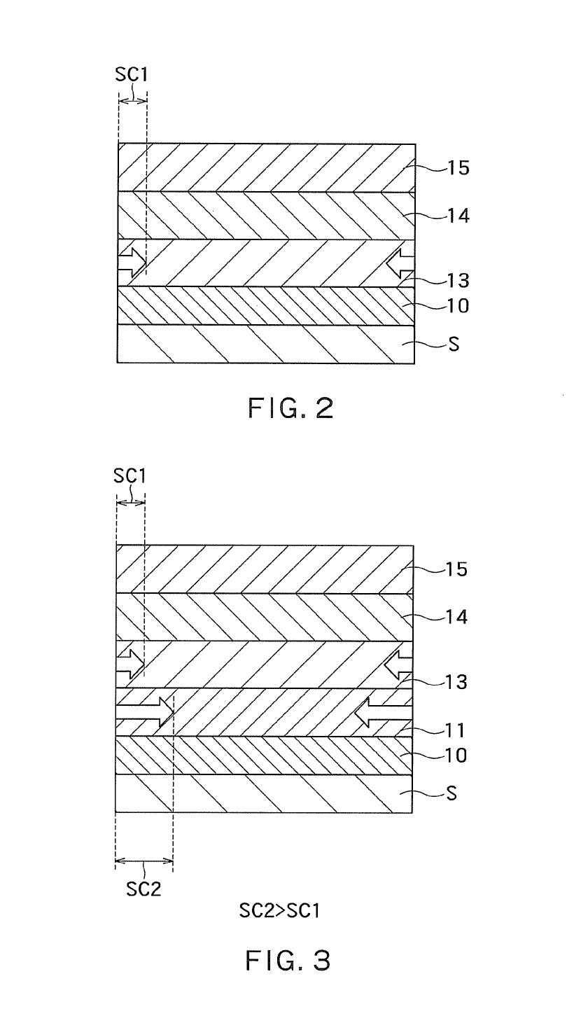

As described above, adding carbon (C) or aluminum (Al) to GaN is important in improving the breakdown voltage. However, the lattice constant of GaN is decreased by the increase in the addition amount of carbon (C) which is an impurity having a small atomic radius or by the increase in an aluminum (Al) molar fraction. This affects the accumulation of compressive stress in the nitride-based semiconductor layer stacked on the buffer layer 10. Specifically, as shown in a reference example in FIG. 2, the compressive stress is not sufficiently accumulated, and it is difficult to obtain an epitaxial growth of nitride-based semiconductor which is crack-free and in high crystalline quality and which has a thick film. On the other hand, if carbon (C) or aluminum (Al) is not added to GaN, the compressive stress is easily accumulated, but the problem is that obtaining a sufficient breakdown voltage is difficult.

Thus, in the present embodiment, the undoped-GaN layer 11 is provided as a stress control layer between the buffer layer 10 and the C-AlₓGa₁₋ₓN layer 13.

The accumulation of compressive stress in the semiconductor device according to the present embodiment is schematically shown in FIG. 3. As shown in FIG. 3, the high-quality u-GaN layer 11 having a low impurity concentration can accumulate more compressive stress during growth than the C-AlₓGa₁₋ₓN layer 13 having a high impurity concentration. Thus, crystal growth for the high-quality u-GaN layer 11 can be finished with sufficient compressive stress remaining accumulated in the nitride-based semiconductor layer even if the C-AlₓGa₁₋ₓN layer 13 and the i-GaN layer 14 are stacked on the u-GaN layer 11 later. A relation SC2>SC1 is satisfied for the same stacked film thickness, wherein SC1 is the degree of the compressive stress accumulated in the C-AlₓGa₁₋ₓN layer 13 during growth, and SC2 is the degree of the compressive stress accumulated in the u-GaN layer 11 during growth. Consequently, the stress in a wafer can be controlled by the u-GaN layer 11, and even when the thickness of the nitride-based semiconductor layer is grown, it is possible to obtain a crack-free wafer which has a satisfactory surface flatness at the end of crystal growth and which has a convex bow. Moreover, a semiconductor device which uses a GaN-on-Si epitaxial substrate and which has a breakdown voltage of 1000 V or more is obtained.

Since the C-AlₓGa₁₋ₓN layer 13 contains high-concentration impurity, the C-AlₓGa₁₋ₓN layer 13 does not tend to have a flat surface not only when influenced by the decrease in the accumulation of the compressive stress due to the small atomic radius of the C-AlₓGa₁₋ₓN layer 13 but also when the u-GaN layer 11 is not interposed on the buffer layer 10. The growth mode of the nitride-based semiconductor layer tends to be three-dimensional, and this also means that the interposition of the u-GaN layer 11 is effective because the effect on the accumulation of the compressive stress is small.

When the u-GaN layer 11 is interposed, the nitride-based semiconductor layer tends to be a film having a flat surface, that is, the accumulation of the compressive stress is accelerated. Therefore, the C-AlₓGa₁₋ₓN layer 13 may not only contain an impurity having a small atomic radius but also contain, for example, a transition metal of about 1×10¹⁸ cm⁻², such as Fe, Mg, or Zn.

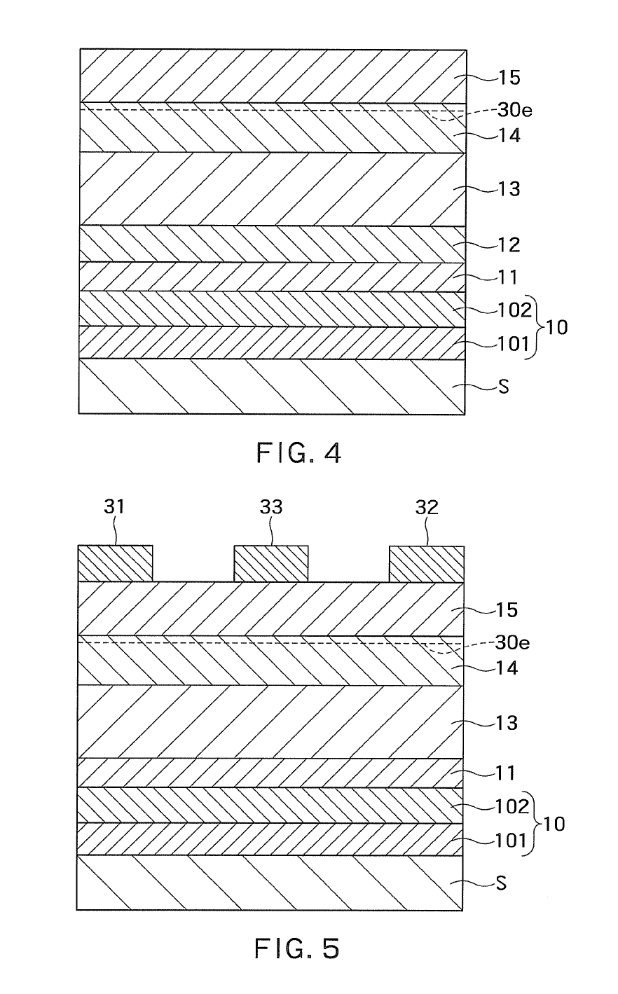

FIG. 4 is an example of a schematic sectional view showing one modification of the semiconductor device shown in FIG. 1. As obvious from the contrast with FIG. 1, the semiconductor device according to the present modification further includes an AlN layer 12 provided so as to be interposed between the u-GaN layer 11 and the C-AlₓGa₁₋ₓN layer 13. Thanks to the interposition of the AlN layer 12, compressive stress is more easily accumulated in the C-AlₓGa₁₋ₓN layer 13 when a lattice constant difference is intentionally made. As a result, the u-GaN layer 11 can be thinner. In the present example, the thickness of the u-GaN layer 11 is, for example, 50 nm or more and 300 nm or less, and the thickness of the AlN layer 12 is, for example, 5 nm or more and 50 nm or less.

### (2) Embodiment 2

FIG. 5 is an example of a schematic sectional view showing the general structure of a semiconductor device according to Embodiment 2.

As obvious from the contrast with FIG. 1, the semiconductor device according to the present embodiment enables a horizontal high electron mobility transistor (HEMT) to be obtained by further providing the semiconductor device shown in FIG. 1 with electrodes 31 to 33.

More specifically, the semiconductor device shown in FIG. 5 includes a source (or drain) electrode 31, a drain (or source) electrode 32, and a gate electrode 33, in addition to a semiconductor device in which a substrate S, a buffer layer 10, a u-GaN layer 11, a C-AlₓGa₁₋ₓN layer 13, an i-GaN layer 14, and an AlₓGaN layer 15 are stacked in this order. The buffer layer 10 includes an AlN layer 101, and an AlGaN layer 102 provided on the AlN layer 101 in contact with the AlN layer 101.

The source (or drain) electrode 31 and the drain (or source) electrode 32 are provided apart from each other on the barrier layer 15, and are formed so as to be ohmic contact with the barrier layer 15. In the present embodiment, the source (or drain) electrode 31 and the drain (or source) electrode 32 correspond to, for example, first and second electrodes, respectively.

The gate electrode 33 is formed on the barrier layer 15 between the source (or drain) electrode 31 and the drain (or source) electrode 32. In the present embodiment, the gate electrode 33 corresponds to, for example, a control electrode.

Although not shown in FIG. 5, insulating films may be formed in regions on the barrier layer 15 between the electrodes 31 to 33. A gate insulating film (not shown) may be interposed between the gate electrode 33 and the barrier layer 15.

The semiconductor device according to at least one of the embodiments described above includes a semiconductor device having GaN in which compressive stress is accumulated, so that a robust semiconductor device having a high breakdown voltage is provided.

While certain embodiments have been described, these embodiments have been presented by way of example only, and are not intended to limit the scope of the inventions.

For example, although a stack of the AlN layer 101 and the AIGaN layer 102 is used as the buffer layer 10 in the embodiments described above, a multilayer film having a superlattice structure may be used instead of the buffer layer 10. Here, the “superlattice structure” refers to a structure in which, for example, 20 pairs of AlN layers and GaN layers are alternately stacked in such a manner that each pair includes, for example, an AlN layer having a thickness of 5 nm and a GaN layer having a thickness of 20 nm.

Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a GaN layer; and
a first AlₓGa₁₋ₓN layer (0≦X<1) in contact with the GaN layer, which comprises carbon (C).

2. The device of claim 1,
wherein the GaN layer comprises at least one of substances selected from the group consisting of carbon (C), oxygen (O), and silicon (Si) which are less than 5×10¹⁷ cm⁻³ in concentration, respectively.

3. The device of claim 1,
wherein the threading dislocation density of the first AlₓGa₁₋ₓN (0≦X<1) layer is less than 2×10⁹ cm⁻².

4. The device of claim 1,
wherein the thickness of the GaN layer is 100 nm or more and 2 μm or less.

5. The device of claim 1,
wherein the thickness of the AlₓGa₁₋ₓN layer is 500 nm or more and 10 μm or less.

6. The device of claim 1,
wherein the first AlₓGa₁₋ₓN (0≦X<1) layer further comprises a transition metal of 1×10¹⁸ cm⁻² or less.

7. The device of claim 1, further comprising an i-GaN layer on the first AlₓGa₁₋ₓN (0≦X<1) layer,
wherein the impurity concentration of the i-GaN layer is lower than the impurity concentration of the GaN layer.

8. The device of claim 7,
wherein the i-GaN layer comprises at least one of substances selected from the group consisting of carbon (C), oxygen (O), and silicon (Si) which are less than 3×10¹⁷ cm⁻³ in concentration, respectively.

9. The device of claim 1, further comprising
an i-GaN layer on the first AlₓGa₁₋ₓN (0≦X<1) layer;
a second AlₓGa₁₋ₓN layer on the i-GaN layer;
first and second electrodes on the second AlₓGa₁₋ₓN layer, which are apart from each other; and
a control electrode between the first and second electrodes on the second AlₓGa₁₋ₓN layer.

10. A semiconductor device comprising:
a GaN layer;
an AlN layer in direct contact with the GaN layer; and
a first AlₓGa₁₋ₓN layer (0≦X<1) in direct contact with the AlN layer, which comprises carbon (C).

11. The device of claim 10,
wherein the thickness of the GaN layer is 50 nm or more and 300 nm or less, and
the thickness of the first AlₓGa₁₋ₓN (0≦X<1) layer is 5 nm or more and 50 nm or less.

12. The device of claim 10,
wherein the GaN layer comprises at least one of substances selected from the group consisting of carbon (C), oxygen (O), and silicon (Si) which are less than 5×10¹⁷ cm⁻³ in concentration, respectively.

13. The device of claim 10,
wherein the threading dislocation density of the first AlₓGa₁₋ₓN (0≦X<1) layer is less than 2×10⁹ cm⁻².

14. The device of claim 10,
wherein the thickness of the GaN layer is 100 nm or more and 2 μm or less.

15. The device of claim 10,
wherein the thickness of the AlₓGa₁₋ₓN layer is 500 nm or more and 10 μm or less.

16. The device of claim 10,
wherein the first AlₓGa₁₋ₓN (0≦X<1) layer further comprises a transition metal of 1×10¹⁸ cm⁻² or less.

17. The device of claim 10, further comprising an i-GaN layer on the first AlₓGa₁₋ₓN (0≦X<1) layer,
wherein the impurity concentration of the i-GaN layer is lower than the impurity concentration of the GaN layer.

18. The device of claim 17,
wherein the i-GaN layer comprises at least one of substances selected from the group consisting of carbon (C), oxygen (O), and silicon (Si) which are less than 3×10¹⁷ cm⁻³ in concentration, respectively.

19. The device of claim 10, further comprising
an i-GaN layer on the first AlₓGa₁₋ₓN (0≦X<1) layer;
a second AlₓGa₁₋ₓN layer on the i-GaN layer;
first and second electrodes on the second AlₓGa₁₋ₓN layer, which are apart from each other; and
a control electrode between the first and second electrodes on the second AlₓGa₁₋ₓN layer.
